(19) United States
(12) Patent Application Publication
(10) Pub. No.: US 2009/0273891 A1
(43) Pub. Date: Nov. 5, 2009

(54) RECEIVING DEVICE

(76) Inventor: Andreas PEIKER, Friedrichsdorf (DE)

Correspondence Address: BURR & BROWN, PO BOX 7068, SYRACUSE, NY, 13261-7068, US

(21) Appl. No.: 12/498,554

(22) Filed: Jul. 7, 2009

Related U.S. Application Data
(63) Continuation of application No. PCT/DE2008/000149, filed on Jan. 28, 2008.

(30) Foreign Application Priority Data
Jan. 29, 2007 (DE) 10 2007 005 158.3

(51) Int. Cl. H05K 7/00; H02J 7/00

(52) U.S. Cl. 361/679.01; 320/108

(57) ABSTRACT

The invention relates to a receiving device for integrating therein a portable, electronic appliance, especially a mobile phone in a vehicle, said receiving device having a receiving zone for the portable, electronic appliance and the receiving device having an interface to the portable, electronic appliance and an interface to electrical or electronic components that are arranged in the vehicle. The receiving device can be physically separated into an upper part and a lower part, the upper part being specifically adapted to a certain model of a portable, electronic appliance, and the lower part being specifically adapted to a product family and/or a specific range of portable, electronic appliances. The lower part can be combined and assembled with a plurality of different upper parts to give specific receiving devices or the upper part can be combined and assembled with a plurality of different lower parts to give additional specific receiving devices.

### CROSS REFERENCE TO RELATED APPLICATIONS

This application is a continuation of International Application No. PCT/DE2008/000149, filed Jan. 28, 2008, which designated the United States, and claims the benefit under 35 USC §119(a)-(d) of German Application No. 10 2007 005 158.3 filed Jan. 29, 2007, the entireties of which are incorporated herein by reference.

### FIELD OF THE INVENTION

The invention relates to a receiving apparatus for portable electronic appliances.

### BACKGROUND OF THE INVENTION

WO 02/057117 A2 discloses a receiving apparatus for incorporating a portable, electronic appliance, particularly a mobile telephone, into a vehicle, wherein the receiving apparatus has a receiving area for the portable, electronic appliance and wherein the receiving apparatus has an interface for the portable, electronic appliance and an interface to electrical or electronic components which are arranged in the vehicle. The receiving apparatus is respectively configured and designed for a particular type of portable, electronic appliance.

### SUMMARY OF THE INVENTION

The invention is based on the object of developing a receiving apparatus which can be produced inexpensively for a multiplicity of different portable, electronic appliances.

The receiving apparatus according to the invention can be physically separated at least into a top part and a bottom part, wherein the top part specifically matches a particular model of a portable, electronic appliance, and the bottom part specifically matches a product family and/or a specific scope of services. The bottom part can be assembled with a multiplicity of different top parts to form specific receiving apparatuses or the top part can be assembled with a multiplicity of different bottom parts to form further specific receiving apparatuses. This means that it is possible to take a comparatively small number of top parts and bottom parts and produce suitable receiving apparatuses for a large number of different portable, electronic appliances. It is therefore no longer necessary to provide a complete receiving apparatus specifically designed for each electronic appliance. Rather, it is possible to resort to the same bottom part for portable, electronic appliances which have identical or compatible interface specifications. This ability to combine a bottom part with a multiplicity of top parts means that the bottom part can be produced in greater quantities and thus also less expensively. Identical and compatible interface specifications can usually be found among appliances in one product family from a manufacturer. It is also conceivable for the same top parts to be combined with different bottom parts, for example when particular functional features, such as a GPS receiver, are provided as special equipment by a specific bottom part and different electronic appliances can be held with the same top part. A main object of the invention is matching the top part to a multiplicity of different, portable, electronic appliances and combining these top parts with a smaller number of bottom parts which are respectively suitable for a plurality of different, portable, electronic appliances. The invention makes use of the commonalities of different, portable, electronic appliances for cost optimization when producing receiving apparatuses which are respectively specialized in the individual appliance type.

The invention provides for the top part to contain the receiving area, which, as a receiving space, matches geometrical dimensions of the portable, electronic appliance. This allows the different portable, electronic appliances to be held securely.

In addition, the invention provides for the top part to contain a coupling antenna which is oriented to and matches an antenna arranged in the portable, electronic appliance. It also allows appliances without an antenna connector to be operated with the receiving apparatus according to the invention.

The invention provides for the top part to contain the interface to the portable, electronic appliance. This completely matches the top part to the specific portable, electronic appliance.

The invention provides for the interface to the portable, electronic appliance to be in the form of a multiterminal contact for the data interchange and/or in the form of a multiterminal charging contact for the transmission of power to the portable, electronic appliance and/or in the form of a transmission and/or reception device for wireless signals. This allows the greatest diversity of portable, electronic appliances to be incorporated into the receiving device in line with their individual requirements.

The invention also provides for the interface to be illuminated by a transparent component, which can be used as a light guide, from an interior of the receiving apparatus. This signals to the user, simply and clearly, how the portable, electronic appliance needs to be inserted into the receiving apparatus or to be coupled to the receiving area of the top part, since the user is regularly aware of the position of the interface on his portable, electronic appliance.

In particular, the invention provides for the interface of the receiving apparatus to the portable, electronic appliance to be held on the top part in the receiving area by the transparent component. As a result, the transparent component undertakes a holding function in addition to its illumination function and thus results in a receiving apparatus which comprises only a few components.

It is also possible for the top part to contain an electrical coil which is oriented to a coil arranged in the portable, electronic appliance, in order to contactlessly or inductively charge an energy store in the portable, electronic appliance. This makes it possible to dispense with electrical contacts for power transmission. A receiving apparatus of this kind is therefore also suitable for use in construction site vehicles, for example, since the power transmission is not adversely affected even by a high level of dust exposure.

The invention also provides for at least one operator control element to be arranged on the top part and/or the bottom part. This makes it a particularly simple matter to select particularly important functions of the portable, electronic appliance or special functions which are provided by the receiving apparatus. By way of example, provision is made for an operator control element of this kind to have an assigned emergency call function.

In particular, the invention provides for the operator control element to be in the form of an electromechanical pushbutton switch or electromechanical switch or in the form of an electronic pushbutton switch or in the form of a touch-sensitive display device or “touchscreen”, in order to match it to the respective requirements in an efficient manner.

In particular, the invention provides for the electronic pushbutton switch to be in the form of a capacitive pushbutton switch which reacts to a change of capacitance or to a disturbance injection by an approaching finger. This allows the receiving device to be produced in a simple and nevertheless robust form in the area of the operator control element(s), since the housing does not need to be provided with openings for moving components.

The invention provides for the bottom part to contain an electronics unit. The comparatively expensive electronics unit can in this way be used for a multiplicity of top parts or portable, electronic appliances and can therefore be produced inexpensively in larger quantities.

Provision is also made for the bottom part and the top part to have a data link for data transmission and/or a power link for power transmission set up between them when joined. This ensures time-saving final assembly.

In particular, wireless data transmission between the bottom part and the top part is provided. This makes it possible to dispense with sensitive contact elements between the top part and the bottom part.

Wireless power transmission between the bottom part and the top part is also provided. This also simplifies joining and separating of the top part and the bottom part.

Finally, the invention provides the bottom part and/or the top part with a shaft for receiving and making contact with data stores and/or modules. This allows the receiving apparatus to be retrofitted with memory, computation power or additional functions. For example, the module provided is a GSM receiver.

### BRIEF DESCRIPTION OF THE DRAWINGS

Further details of the invention are described in the drawing with reference to schematically illustrated exemplary embodiments, in which:

FIG. 1 shows a plan view of a receiving apparatus according to the invention;

FIG. 2 shows a side view of the receiving apparatus shown in FIG. 1;

FIG. 3 shows an exploded illustration of a sectional view of the receiving apparatus shown in FIG. 2;

FIG. 4 shows a schematic illustration of the set of receiving apparatuses for a first appliance family;

FIG. 5 shows a schematic illustration of the set of receiving apparatuses for a second appliance family; and

FIG. 6 shows a schematic illustration of a second receiving apparatus according to the invention.

### DETAILED DESCRIPTION OF THE INVENTION

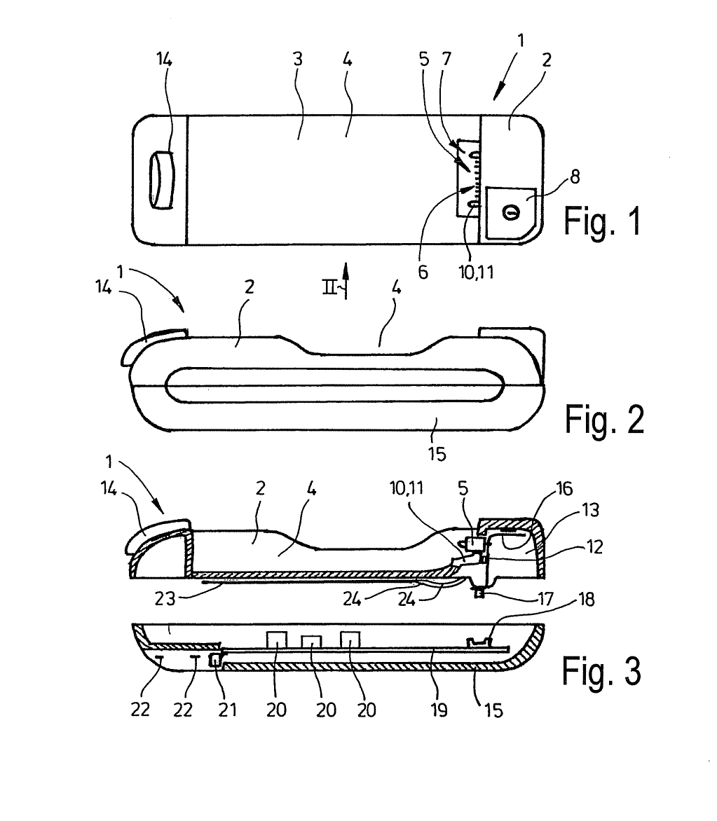

FIG. 1 shows a plan view of a receiving apparatus 1. The plan view shows a top part 2 of the receiving apparatus 1. The top part 2 has a receiving area 3 for a portable, electronic appliance (not shown). The receiving area 3 is in the form of a receiving space 4 which is attuned to geometrical dimensions of the portable, electronic appliance. The receiving space 4 contains an interface 5 by means of which it is possible to make contact with the portable, electronic appliance in order to transmit data and power. The interface 5 comprises a multiterminal contact 6 for data transmission and a multiterminal contact 7 for power transmission, the data transmission possibly also being intended to be understood to mean the transmission of antenna signals. Beside the receiving space 4, the top part 2 of the receiving apparatus 1 holds an operator control element 8. The operator control element 8 is in the form of an electronic pushbutton switch which comprises, as an essential component, a capacitive sensor which reacts to the operator control element 8 being touched by a finger. The operator control element 8 can be used to activate and deactivate the receiving apparatus 1. The interface 5 is mounted on the top part 2 by a component 10, particularly a translucent frame. The component 10 has properties of a light guide 11 and is illuminated by a light emitting diode 12 from an interior 13 of the top part 2 (see also FIG. 3). The top part 2 also holds an unlocking key 14 which can be used to eject the electronic appliance from the receiving space 4.

FIG. 2 shows a side view of the receiving apparatus 1 known from FIG. 1 from an arrow direction II. In the side view, a bottom part 15 can now also be seen beneath the top part 2. The top part 2 and the bottom part 15 have been assembled to form the receiving device 1.

FIG. 3 shows the receiving apparatus 1 shown in FIG. 2, this time in section and in an exploded illustration. The top part 2 comprises not only the components described above but also a flexible printed circuit board 16 which connects the electronic pushbutton switch 9, the interface 5 and the light emitting diode 12 to a further interface 17. This interface 17 is used for transmitting data and/or power between the top part 2 and the bottom part 15. The interface 17 interacts with an interface 18 in the bottom part 15 when the top part 2 and the bottom part 15 are joined—as shown in FIG. 2. The interface 18 is arranged on a main printed circuit board 19 in the bottom part 15. The main printed circuit board 19 holds electronics unit 20 and electronic components, which can be used for a plurality of types of portable, electronic appliances. The main printed circuit board 19 also has an interface 21 connected to it by means of which the receiving apparatus 1 can have contact made with it by electrical and/or electronic components (not shown) arranged in the vehicle—possibly with at least one further component interposed. The bottom part 15 has guides 22 formed on it which make it easier for the interface 21 to have contact made with it by a further interface (not shown) and also allow the receiving device 1 to be mechanically mounted or held on the vehicle. Finally, FIG. 3 also shows a coupling antenna 23 which is arranged on the top part 2 beneath the receiving space 4. This coupling antenna 23 can be used to tap off the antenna signal from a portable, electronic appliance located in the receiving space 4 in order to route said antenna signal to an external antenna on the vehicle. The coupling antenna 23 is connected to the flexible printed circuit board 16 by means of signal lines 24.

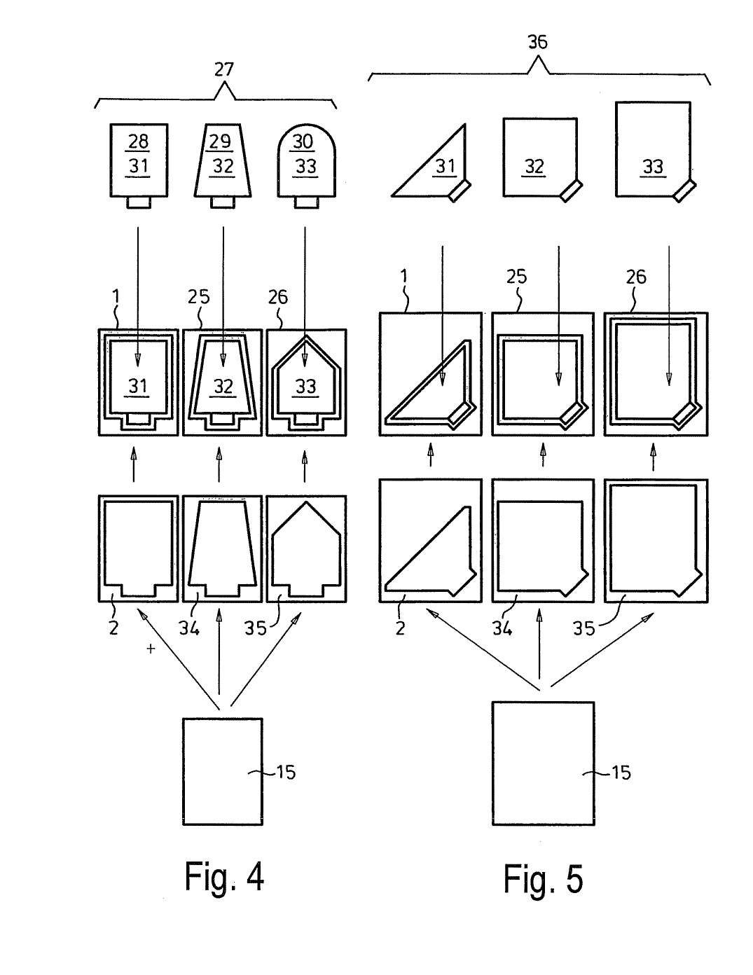

FIG. 4 shows various receiving apparatuses 1, 25 and 26 for a family 27 of various portable, electronic appliances 28, 29 and 30. The portable, electronic appliances 28, 29 and 30 are in the form of mobile telephones 31, 32 and 33. The individual receiving apparatuses 1, 25, 26 are assembled from the same bottom parts 15 and different top parts 2, 34 and 35 to form the receiving apparatuses 1, 25 and 26. The same bottom parts 15 contain essentially those electronic components which can be used for the mobile telephones 31, 32 and 33 in the family 27 in the same way.

In a similar manner to FIG. 4, FIG. 5 shows a further family 36 of mobile telephones 31, 32 and 33. These mobile telephones 31, 32 and 33 also have individual receiving apparatuses 1, 25 and 26 assembled from the same bottom parts 15 and top parts 2, 34 and 35 that are specifically designed for the individual mobile telephones 31, 32 and 33.

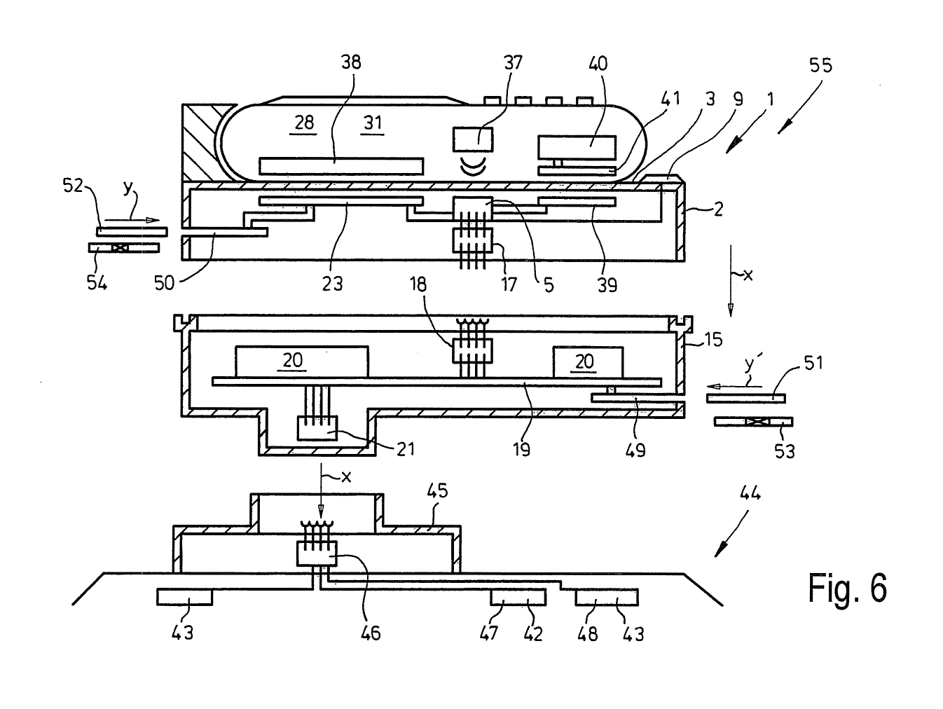

FIG. 6 shows a schematic illustration of a second receiving apparatus 1 according to the invention. The receiving apparatus 1 comprises two assemblable half-shells which are in the form of top part 2 and bottom part 15. A receiving area 3 of the top part 2 stores a mobile telephone 31 as portable, electronic appliance 28. The top part 2 contains an interface 5 by means of which the top part 2 communicates wirelessly with an interface 37 on the mobile telephone 31. An antenna 38 on the mobile telephone 31 interacts with a coupling antenna 23, which is likewise arranged in the top part 2. An electrical coil 39 in the top part 2 can be used to supply power inductively to a rechargeable battery 40 in the mobile telephone 31, the power being received using a coil 41 which is arranged in the mobile telephone 31. An electrical pushbutton switch 9 can be used to switch on and switch off the receiving apparatus 1. Placing the top part 2 onto the bottom part 15 in an arrow direction x sets up contact between interfaces 17 and 18. A main printed circuit board 19 arranged in the bottom part 15 connects the interface 18 to an electronics unit 20 arranged on the main printed circuit board 19 and to a further interface 21. To make contact between electrical components 42 and electronic components 43 in a vehicle 44, the entire receiving apparatus 1 is put onto a holding apparatus 45 in the arrow direction x, said holding apparatus having an interface 46 which is then in contact with the interface 21 on the bottom part 15. The holding apparatus 45 therefore mechanically holds and makes electrical contact with the receiving apparatus 1. The interface 46 connects the electrical components 42 and the electronic components 43. Within the context of the invention, an electrical component 42 is understood to mean an electromechanical switch 47 arranged in the vehicle 44, for example. An electronic component 43 within the context of the invention is understood to mean a display apparatus 48 arranged in the vehicle 44, for example. In addition, the bottom part 15 and the top part 2 of the receiving apparatus have a respective shaft 49, 50 into which, by way of example, electronic memory cards 51, 52 or GSM modules 53, 54 can be inserted in an arrow direction y′ or y in order to equip the receiving apparatus 1 with additional functions. Together with the receiving apparatus 1, the holding apparatus 45 forms a holding and receiving apparatus 55.

The invention is not limited to exemplary embodiments illustrated or described. Rather, it comprises developments of the invention within the context of the patent claims. In particular, the invention also provides for the receiving apparatus to receive two or more portable, electronic appliances.

### REFERENCE SYMBOLS

1 Receiving apparatus
2 Top part of 1
3 Receiving area of 2
4 Receiving space of 2
5 Interface on 2 to 28, 29 or 30
6 Multiterminal data contact of 5
7 Multiterminal charging contact of 5
8 Operator control element
9 Electronic pushbutton switch
10 Component for mounting 5
11 Light guide
12 Light emitting diode in 13
13 Interior of 2
14 Unlocking key on 2
15 Bottom part of 1
16 Flexible printed circuit board in 2
17 Interface of 2 to 15
18 Interface of 15 to 2
19 Main printed circuit board in 15
20 Electronics unit in 15
21 Interface of 15 to 45
22 Guide on 15
23 Coupling antenna in 2
24 Signal line of 23 to 16
25 Second receiving apparatus
26 Third receiving apparatus
27 Family of portable, electronic appliances
28 First portable, electronic appliance
29 Second portable, electronic appliance
30 Third portable, electronic appliance
31 First mobile telephone
32 Second mobile telephone
33 Third mobile telephone
34 Second top part
35 Third top part
36 Family of portable, electronic appliances
37 Interface of 28 or 31
38 Antenna of 31
39 Electrical coil in 5
40 Rechargeable battery in 31
41 Coil in 31
42 Electrical component in 44
43 Electronic component in 44
44 Vehicle
45 Holding apparatus for 1
46 Interface in 45
47 Switch
48 Display device
49 Shaft in 15
50 Shaft in 2
51 Memory card
52 Memory card
53 GSM module
54 GSM module
55 Holding and receiving apparatus
x arrow direction
y arrow direction
y′ arrow direction

What is claimed:

1. An apparatus for incorporating a portable, electronic appliance into a vehicle comprising a receiving apparatus having (i) a receiving area for receiving the appliance, (ii) an interface to the appliance, and (iii) an interface to a holding apparatus which has a connection for at least one of electrical and electronic components that are arranged in the vehicle, wherein the receiving apparatus is physically separable at least into a top part and a bottom part, the top part specifically matching a particular model of an appliance, the bottom part specifically matching at least one of an appliance family and a specific scope of appliance services, such that a given bottom part can be assembled with a plurality of different top parts to form a first specific set of receiving apparatuses and a given top part can be assembled with a plurality of different bottom parts to form a second specific set of receiving apparatuses.

2. The apparatus as claimed in claim 1, wherein the top part has an interface and the bottom part has an interface, and the top part and the bottom part are brought into contact with one another by joining the top part and the bottom part via the interfaces.

3. The apparatus as claimed in claim 1, wherein the receiving area of the top part defines a receiving space that matches geometrical dimensions of the appliance.

4. The apparatus as claimed in claim 1, wherein the top part further comprises a coupling antenna which is oriented to an antenna arranged in the appliance.

5. The apparatus as claimed in claim 1, wherein the top part contains the interface to the appliance.

6. The apparatus as claimed in claim 1, wherein the interface to the appliance is at least one of (i) a multiterminal data contact for data interchange, (ii) a multiterminal charging contact for transmission of power to the appliance and (iii) at least one of a transmission and reception device for wireless signals.

7. The apparatus as claimed in claim 1, further comprising a transparent light guide for illuminating the interface to the appliance from an interior of the receiving apparatus.

8. The apparatus as claimed in claim 7, wherein the interface is positioned on the top part in the receiving area by the transparent light guide.

9. The apparatus as claimed in claim 1, wherein the top part further comprises an electrical coil which is oriented to a coil arranged in the appliance in order to inductively charge a rechargeable battery of the appliance.

10. The apparatus as claimed in claim 1, wherein at least one of the top part and the bottom part has at least one exposed operator control element.

11. The apparatus as claimed in claim 10, wherein the operator control element is one of an electromechanical pushbutton switch, an electromechanical switch, an electronic pushbutton switch, and a touch-sensitive display device.

12. The apparatus as claimed in claim 11, wherein the electronic pushbutton switch is a capacitive pushbutton switch which reacts to one of a change of capacitance and a disturbance injection by an approaching finger.

13. The apparatus as claimed in claim 1, wherein the bottom part further comprises an electronics unit.

14. The apparatus as claimed in claim 1, wherein the bottom part and the top part have at least one of a data link for data transmission and a power link for power transmission set up between them when the top and bottom parts are joined to one another.

15. The apparatus as claimed in claim 1, wherein data transmission between the bottom part and the top part takes place wirelessly.

16. The apparatus as claimed in claim 1, wherein power transmission between the bottom part and the top part takes place wirelessly.

17. The apparatus as claimed in claim 1, wherein at least one of the bottom part and the top part comprises a shaft for receiving and making contact with one of memory cards and modules.

18. The apparatus as claimed in claim 1, wherein the appliance is a mobile telephone.
